(19) United States
(12) Patent Application Publication
(10) Pub. No.: US 2026/0279741 A1
(43) Pub. Date: Sep. 17, 2026

(54) ENCAPSULATED METAL PEDESTAL

(71) Applicant: LAM RESEARCH CORPORATION, Fremont, CA (US)

(72) Inventors: Timothy Scott THOMAS, Wilsonville, OR (US); Ramesh CHANDRASEKHARAN, Lake Oswego, OR (US)

(21) Appl. No.: 19/471,062

(22) PCT Filed: Apr. 3, 2024
(86) PCT No.: PCT/US2024/022748

§ 371 Date: Sep. 30, 2025

Related U.S. Application Data
(60) Provisional application No. 63/458,411, filed on Apr. 10, 2023.

(51) Int. Cl. H01J 37/32; H10P 72/78

(52) U.S. Cl. CPC H01J 37/32715; H01J 37/3244; H10P 72/78; H01J 2237/2007

(57) ABSTRACT

A pedestal for a substrate processing system includes a base portion and a stem portion. The base portion includes a first metallic material. The stem portion is coupled to the base portion. A second metallic material encapsulates the base portion. The second metallic material is different than the first metallic material.

### CROSS-REFERENCE TO RELATED APPLICATIONS

This application claims the benefit of U.S. Provisional Application No. 63/458,411, filed on Apr. 10, 2023. The entire disclosure of the application referenced above is incorporated herein by reference.

### FIELD

The present disclosure relates generally to substrate processing systems and more particularly to an encapsulated metal pedestal used to support substrates in substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems (called tools) are used to treat substrates such as semiconductor wafers. Substrates are treated using various deposition and/or etching processes. For example, the processes can comprise atomic layer deposition (ALD), atomic layer etching (ALE), chemical vapor deposition (CVD), etc. During processing, a substrate is arranged on a substrate support (called a pedestal) in a processing chamber. Various gases, gas mixtures, and/or vaporized precursors are introduced into the processing chamber using a showerhead, an injector, etc. Plasma may be used to initiate chemical reactions. The processing chamber may be cleaned periodically using various cleaning processes, where cleaning gases are introduced into the processing chamber, and plasma may be ignited.

### SUMMARY

A pedestal for a substrate processing system comprises a base portion and a stem portion. The base portion comprises a first metallic material. The stem portion is coupled to the base portion. A second metallic material encapsulates the base portion. The second metallic material is different than the first metallic material.

In additional features, the first metallic material is selected from a group consisting of aluminum, stainless steel, and an alloy of aluminum. The second metallic material is nickel or nickel alloy.

In additional features, the first and second metallic materials are thermally compatible with each other. The second metallic material is more resistant than the first metallic material to chemistries used to process a substrate on the pedestal in a processing chamber of the substrate processing system. The second metallic material is more resistant than the first metallic material to chemistries used to clean the processing chamber.

In additional features, the second metallic material on a top surface of the base portion is thicker than on bottom and side surfaces of the base portion.

In additional features, different areas of the base portion and the stem portion are encapsulated with the second metallic material using different encapsulating methods.

In additional features, the stem portion comprises the second metallic material.

In additional features, the stem portion comprises the first metallic material and the stem portion is encapsulated with the second metallic material.

In additional features, the base portion comprises first, second, third, fourth, and fifth plates. The first plate comprises the first metallic material. The first plate comprises a first surface and a second surface. The second plate comprises the first metallic material. The second plate comprises a first surface and a second surface. The first surface of the second plate is bonded to the second surface of the first plate. Sidewalls of the first and second plates are covered with a first layer of the second metallic material. The third plate comprises the second metallic material. The third plate comprises a first surface and a second surface. The fourth plate comprises the second metallic material. The fourth plate comprises a first surface and a second surface. The first surface of the fourth plate is bonded to the second surface of the third plate. The second surface of the fourth plate is bonded to the first surface of the first plate. The fifth plate comprises the second metallic material. The fifth plate comprises a first surface and a second surface. The first surface of the fifth plate is bonded to the second surface of the second plate. The second surface of the fifth plate is bonded to the stem portion.

In additional features, the third plate is thicker than the fifth plate and thinner than the first plate. The first plate is thicker than the second plate. The fifth plate is thinner than the second plate.

In additional features, the stem portion comprises the first metallic material and is covered with a second layer of the second metallic material. The second layer is thinner than the third and fifth plates and the first layer.

In additional features, the third plate comprises a set of grooves. The pedestal further comprises a conduit coupled to the set of grooves through the stem portion, the fifth plate, the second plate, the first plate, and the fourth plate. The fourth plate seals the first plate from the set of grooves.

In additional features, a system comprises the pedestal and further comprises a vacuum pump coupled to the conduit. The vacuum pump is configured to create vacuum in the set of grooves to clamp a substrate to the first surface of the third plate.

In additional features, a system comprises the pedestal. The third plate comprises a set of holes around a periphery of the first surface of the third plate. The set of holes is in fluid communication with the set of grooves. The system further comprises a gas source coupled to the conduit. The gas source is configured to supply a gas through the set of grooves and the set of holes.

In additional features, the third plate comprises a first set of grooves, a second set of grooves, and a set of holes around a periphery of the first surface of the third plate. The set of holes is in fluid communication with the second set of grooves. The first set of grooves is disjoint from the second set of grooves and the set of holes.

In additional features, the pedestal further comprises a first conduit and a second conduit disposed through the stem portion, the fifth plate, the second plate, the first plate, and the fourth plate. The first conduit is coupled to the first set of grooves. The second conduit is coupled to the second set of grooves. The fourth plate seals the first plate from the first and second sets of grooves and the set of holes.

In additional features, a system comprises the pedestal and further comprises a vacuum pump and a gas source. The vacuum pump is coupled to the first conduit. The vacuum pump is configured to create vacuum in the first set of grooves to clamp a substrate to the first surface of the third plate. The gas source is coupled to the second conduit. The gas source is configured to supply a gas through the second set of grooves and the set of holes.

In additional features, the pedestal further comprises a heater disposed between the first and second plates. An interface between the second plate and the fifth plate comprise gaps is configured to reduce heat transfer from the fifth plate to areas around the pedestal.

In additional features, the pedestal further comprises a heater disposed between the first and second plates. The second surface of the second plate and the first surface of the fifth plate comprise ridges and grooves. The heater is aligned with the ridges on the second surface of the second plate. The ridges on the first surface of the fifth plate are bonded to the grooves on the second surface of the second plate. The grooves on the first surface of the fifth plate are configured to provide gaps around the ridges on the second surface of the second plate. The gaps are configured to reduce heat transfer from the fifth plate to areas around the pedestal.

In additional features, the base portion comprises first, second, third and fourth plates. The first plate comprises the first metallic material. The first plate comprises a first surface and a second surface. The second plate comprises the first metallic material. The second plate comprises a first surface and a second surface. The first surface of the second plate is bonded to the second surface of the first plate. Sidewalls of the first and second plates are covered with a first layer of the second metallic material. The third plate comprises the second metallic material. The third plate comprises a first surface and a second surface. The first surface of the third plate comprises protrusions to support a substrate. The second surface of the third plate is bonded to the first surface of the first plate. The fourth plate comprises the second metallic material. The fourth plate comprises a first surface and a second surface. The first surface of the fourth plate is bonded to the second surface of the second plate. The second surface of the fourth plate is bonded to the stem portion.

In additional features, the third plate is thicker than the fourth plate and thinner than the first plate. The first plate is thicker than the second plate. The fourth plate is thinner than the second plate.

In additional features, the stem portion comprises the first metallic material and is covered with a second layer of the second metallic material. The second layer is thinner than the third and fourth plates and the first layer.

In additional features, the third plate comprises a set of grooves. The pedestal further comprises a conduit coupled to the set of grooves through the stem portion, the fourth plate, the second plate, and the first plate. The pedestal further comprises a fifth plate that seals the first plate from the set of grooves.

In additional features, a system comprises the pedestal. The third plate comprises a set of holes around a periphery of the first surface of the third plate. The set of holes is in fluid communication with the set of grooves. The fifth plate seals the first plate from the set of holes. The system further comprises a gas source coupled to the conduit. The gas source is configured to supply a gas through the set of grooves and the set of holes.

In additional features, the pedestal further comprises a heater disposed between the first and second plates. An interface between the second plate and the fourth plate comprise gaps configured to reduce heat transfer from the fourth plate to areas around the pedestal.

In additional features, the pedestal further comprises a heater disposed between the first and second plates. The second surface of the second plate and the first surface of the fourth plate comprise ridges and grooves. The heater is aligned with the ridges on the second surface of the second plate. The ridges on the first surface of the fourth plate are bonded to the grooves on the second surface of the second plate. The grooves on the first surface of the fourth plate are configured to provide gaps around the ridges on the second surface of the second plate. The gaps are configured to reduce heat transfer from the fourth plate to areas around the pedestal.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 shows an example of a substate processing system comprising an encapsulated pedestal according to the present disclosure;

FIG. 2 shows an example of an un-encapsulate pedestal;

FIG. 3 shows an example of the encapsulated pedestal of FIG. 1 is further detail;

FIG. 4 shows an example of a bottom plate encapsulating a bottom surface of a base portion of the pedestal of FIG. 3 in further detail;

FIG. 5 shows an example of a bottom view of a top plate encapsulating the pedestal of FIG. 3 in further detail;

FIG. 6 shows an example of a top view of the top plate encapsulating the pedestal of FIG. 3 in further detail; and

FIG. 7 shows another example of a top view of the top plate encapsulating the pedestal of FIG. 3 in further detail.

In the drawings, reference numbers may be reused to identify similar and/or identical elements.

### DETAILED DESCRIPTION

Many substrate processing systems use ceramic pedestals instead of metallic pedestals since ceramic pedestals can operate at higher operating temperatures than metallic pedestals and are more resistant to process chemistries than metallic pedestals. For logic applications, the upper operating temperature limit is approximately 450C, which is within thermal capabilities of metallic pedestals (e.g., pedestals made of aluminum, stainless steel, or a metallic alloy). While these metallic pedestals can perform well at these temperatures, these metallic pedestals are not compatible with the process chemistries. For example, these metallic pedestals corrode and flake over time, which causes undesirable contamination in the processing chambers.

The present disclosure provides a metallic pedestal encapsulated with an outer layer of a metallic material different than the metallic material of the pedestal. The metallic material of the outer layer is thermally compatible with the metallic material of the pedestal and is resistant (e.g., to corrosion or erosion due) to process chemistries. For example, the pedestal can be made of aluminum, stainless steel, or an alloy of metallic materials; and the outer layer can be made of nickel. The outer layer may be constructed using several manufacturing methods including metal cladding, friction stir welding, welding, plating, coating, brazing, and diffusion bonding.

The combination of materials used for the pedestal and the outer layer and the manufacturing methods used to encapsulate the pedestal with the outer layer allows using preferred materials for the pedestal and the outer layer. For example, aluminum, stainless steel, or an alloy of metallic materials can be used to manufacture the pedestal due to ease of fabrication and desired thermal conductivity provided by these materials while nickel can be used to form the outer layer due to nickel's thermal compatibility with the material of the pedestal and nickel's chemical compatibility with and resistance to process chemistries.

By using a combination of different manufacturing methods to encapsulate the pedestal with the outer layer, the outer layer with different thicknesses can be used to encapsulate different regions of the pedestal. Thus, by using different materials and different manufacturing methods, a pedestal comprising a hybrid material structure can be manufactured to meet desired thermal and chemical performance requirements that cannot be achieved with a metallic pedestal comprising a single metallic material.

Specifically, as described below in detail, for each portion of the pedestal, a different fabrication method can be used to encapsulate the portion of the pedestal with the outer layer of a thickness that is best suited for that area of the pedestal. For example, on the top surface of the pedestal, where a substrate is placed during processing and where thermal and chemical harshness is most pronounced during processing, a thick plate of nickel can be bonded using a cladding technique or friction stir welding to yield the desired thermal connection between the nickel surface and the aluminum core of the pedestal. The cladding technique or friction stir welding allows for the nickel layer on the top surface of the pedestal to be thicker than plating or coating, which is beneficial for allowing various surface features (e.g., grooves and through holes for vacuum clamping and for supplying edge gases) to be machined into the nickel layer without penetrating into the aluminum below the nickel layer.

Friction stir welding can be used instead of cladding in areas of the pedestal where non-planar surfaces are desirable at the nickel/aluminum interface, or when gaps or channels are to be provided in the nickel layer. For example, such areas include areas on the bottom side of the pedestal where gas channels pass through the pedestal, or gaps (cavities) are included in the nickel layer to minimize thermal conductivity between components. The gaps in the nickel layer on the bottom surface of the pedestal can reduce heat loss from the pedestal to the processing chamber or other components adjacent to the pedestal. The gaps eliminate costly heat shields that are otherwise used between the pedestal and adjacent chamber surfaces or components to reduce heat transfer from pedestal. Plating and/or coating techniques can be used to encapsulate other areas of the pedestal such as sidewall, stem, and internal passages of the pedestal with thinner layers of nickel since thermal and chemical harshness is less pronounced in these areas than on the top surface of the pedestal. These and other features of the present disclosure are described below in detail.

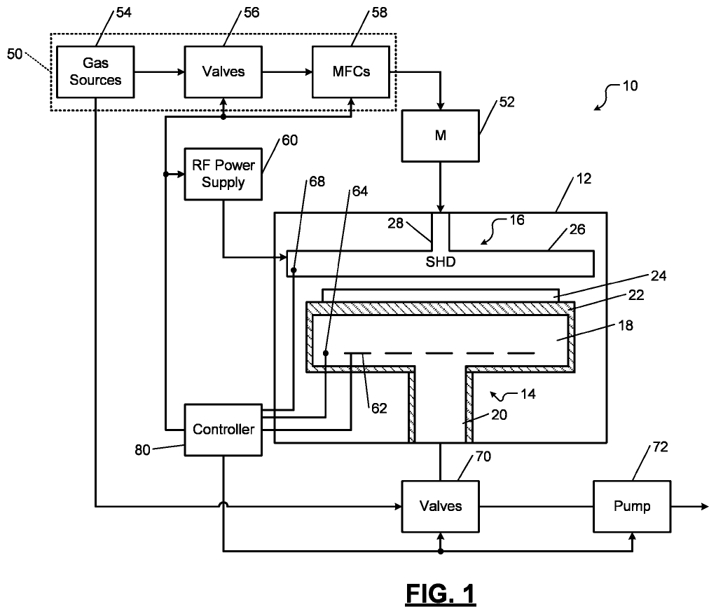

FIG. 1 shows an example of a substrate processing system 10. The substrate processing system 10 comprises a processing chamber 12. The processing chamber 12 comprises a pedestal 14 and a showerhead 16. The pedestal 14 comprises a base portion 18 and a stem portion 20. The stem portion 20 extends from base portion 18 and is coupled to the bottom of the processing chamber 12. The base portion 18 and the stem portion 20 comprise a first metallic material. The base portion 18 of the pedestal 14 is encapsulated with a second metallic material 22. The second metallic material 22 is different than the first metallic material. For example, the first metallic material comprises aluminum, stainless steel, or an alloy of metallic materials; and the second metallic material 22 comprises nickel or nickel alloy. In some examples, the first metallic material is aluminum, stainless steel, or an alloy of aluminum and the second metallic material is nickel.

The second metallic material 22 is thermally compatible with the first metallic material (e.g., in terms of coefficient of thermal expansion or CTE). For example, the CTEs of the first and second metallic materials match closely (e.g., are within a narrow range) so as to prevent deformation (e.g., warping, cracking, contact deterioration, etc.) of either material due to heat. The second metallic material 22 is not only chemically compatible with process chemistries used in the processing chamber 12 but is also more resistant to corrosion or erosion caused by process chemistries used in the processing chamber 12 than the first metallic material. That is, the second metallic material 22 does not alter chemical characteristics of the process chemistries nor alters its own chemical properties due to exposure to process chemistries. Consequently, the second metallic material 22 protects the first material of the pedestal 14 from exposure to process chemistries and prevents the pedestal 14 from corroding and flaking over time, which prevents contamination in the processing chamber 12. The second metallic material 22 is connected to the first metallic material at different regions of the base portion 18 and the stem portion 20 using different methods as described below in detail. In some examples, the stem portion 20 may be made entirely from the second metallic material. During processing, a substrate 24 is arranged on a top surface of the second metallic material 22 that covers a top surface of the base portion 18 of the pedestal 14.

The showerhead 16 comprises a base portion 26 and a stem portion 28. The base portion 26 of the showerhead 16 is cylindrical. The stem portion 28 of the showerhead 16 extends from the base portion 26 of the showerhead 16. The stem portion 28 of the showerhead 16 is attached to a top plate of the processing chamber 12. The stem portion 28 of the showerhead 16 receives various gases (e.g., process gases, cleaning gases, etc.) from a gas delivery system 50 via a manifold 52. The base portion 26 of the showerhead 16 comprises a faceplate comprising through holes or slots (not shown) through which the gases are introduced into the processing chamber 12.

The substrate processing system 10 comprises the gas delivery system 50. The gas delivery system 50 comprises gas sources 54, valves 56, and mass flow controllers (MFCs) 58. The gas sources 54 supply various gases such as process gases, inert gases (also called purge gases, edge gases, carrier gases), cleaning gases, etc. The valves 56 are connected to the gas sources 54 and can be controlled to supply the gases to the MFCs 58. The MFCs 58 regulate the flow of gases to the manifold 52. The manifold supplies the gases or gas mixtures to the showerhead 16.

The substrate processing system 10 comprises a radio frequency (RF) power supply 60. The RF power supply supplies RF power to the showerhead 16 during processing of the substrate 24 and during cleaning of the processing chamber 12. The RF power excites the gases (e.g., process gases, cleaning gases) introduced into the processing chamber 12 to generate plasma between the showerhead 16 and the pedestal 14.

The base portion 18 of the pedestal 14 comprises a heater 62. The heater 62 heats the base portion 18 of the pedestal 14, which in turn heats the substrate 24. The base portion 18 of the pedestal 14 comprises a temperature sensor 64 to sense the temperature of the pedestal 14.

The base portion 26 of the showerhead 16 may also comprise a heater (not shown) to heat the gases being introduced into the processing chamber 12. The base portion 26 of the showerhead 16 may comprise a temperature sensor 68 to sense the temperature of the showerhead 16.

The substrate processing system 10 comprises another set of valves 70. An edge gas from one of the gas sources 54 is introduced into the pedestal 14 via one of the valves 70. The edge gas flows around the edges of the substrate 24 to control processing (e.g., deposition, etching) at the edges (bevel) of the substrate 24. A vacuum pump 72 is connected to the pedestal 14 via another one of the valves 70. To clamp the substrate 24, the vacuum pump 72 creates vacuum on the top surface of the second metallic material 22 that covers the top surface of the base portion 18 of the pedestal 14.

Alternatively, while not shown, the pedestal 14 may use other type of support mechanisms to support the substrate 24. For example, the substrate 24 may be supported by mesas disposed on the top surface of the second metallic material 22 that covers the top surface of the base portion 18 of the pedestal 14. Mesas are tiny protrusions, also called minimum contact areas (MCAs), that can be of different shapes (e.g., cylindrical or polygonal). Regardless of the schemes used to support the substrate 24, the base portion 18 of the pedestal 14 is encapsulated with a second metallic material 22 as described below in further detail.

The substrate processing system 10 comprises a controller 80. The controller 80 controls the valves 56 and 70, the MFCs 58, the heaters in the pedestal 14 and the showerhead 16, the RF power supply 60, the supply of the coolant from the coolant supply 66 to the pedestal 14 and the showerhead 16, and the vacuum pump 72. The controller 80 monitors the temperatures of the pedestal 14 and the showerhead 16 using the temperature sensors 64 and 68 in the pedestal 14 and the showerhead 16. The controller 80 controls the temperatures of the pedestal 14 and the showerhead 16, by controlling the heaters in the pedestal 14 and the showerhead 16 and by controlling the supply of the coolant from the coolant supply 66 to the pedestal 14 and the showerhead 16.

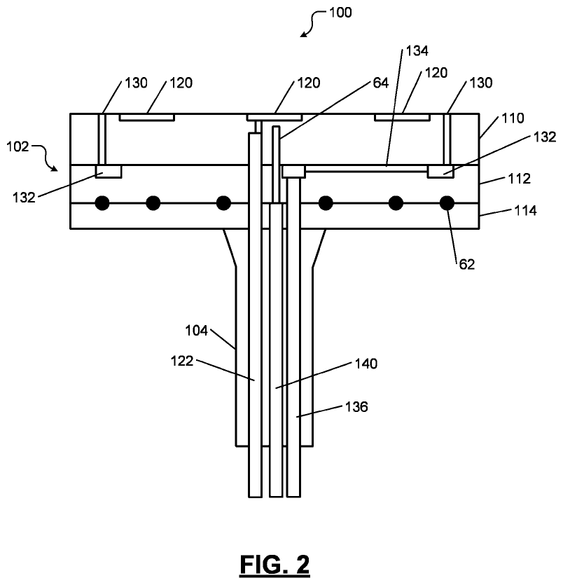

FIG. 2 shows an example of a pedestal 100 comprising the first metallic material. The pedestal 100 is not encapsulated with the second metallic material as described below in further detail. The pedestal 100 can be used in the processing chamber 12 (shown in FIG. 1). The pedestal 100 comprises a base portion 102 and a stem portion 104. For example, the base portion 102 comprises three cylindrical plates 110, 112, 114. The plates 110, 112, 114 comprise the first metallic material. The plates 110, 112, 114 are brazed together to form the base portion 102 of the pedestal 100.

In the base portion 102 of the pedestal 100, the plate 110 comprises grooves 120 on a top surface of the plate 110. The grooves 120 are annular. The grooves 120 are interconnected by radially extending grooves (not shown). A conduit 122 extends through the stem portion 104 of the pedestal 100, passes through the plates 114, 112, and 110, and is connected to the groove 120 near the center of the plate 110. The conduit 122 is connected to the vacuum pump 72 (shown in FIG. 1). The vacuum pump 72 creates vacuum through the annular and radial grooves to clamp the substrate 24 to the top surface of the plate 110.

The plate 110 also comprises an annular groove 130 along the outer periphery of the top surface of the plate 110. The groove 130 is not in fluid communication with the grooves 120. The plate 112 comprises grooves 132 and 134 that are connected to each other and that are in fluid communication with the groove 130 in the plate 110. A conduit 136 extends through the stem portion 104 of the pedestal 100, passes through the plates 114 and 112, and is connected to the groove 134 near the center of the plate 112. The conduit 136 supplies the edge gas through the grooves 134, 132, 130 to control processing around edges of the substrate 24.

A heater (e.g., the heater 62 shown in FIG. 1) is disposed between the plates 112 and 114. A temperature sensor (e.g., the temperature sensor 64 shown in FIG. 1) is disposed in the plate 110 (or can be disposed in the plate 112 instead). A conduit 140 extends through the stem portion 104 of the pedestal 100 and passes through the plate 114. Electrical connections to various components of the pedestal 100 such as the heater 62 and the temperature sensor 64 are provided through the conduit 140. The electrical connections are connected to the controller 80 (shown in FIG. 1).

As described above, the first metallic material used to form the pedestal 100 can withstand the temperatures used by various processes performed in the processing chamber 12 (e.g., substrate processing and chamber cleaning). However, the first metallic material used to form the pedestal 100 cannot withstand the chemical harshness of the process chemistries used in these processes and deteriorates (e.g., corrodes, flakes) over time. The particles resulting from erosion of the pedestal 100 contaminates the processing chamber 12.

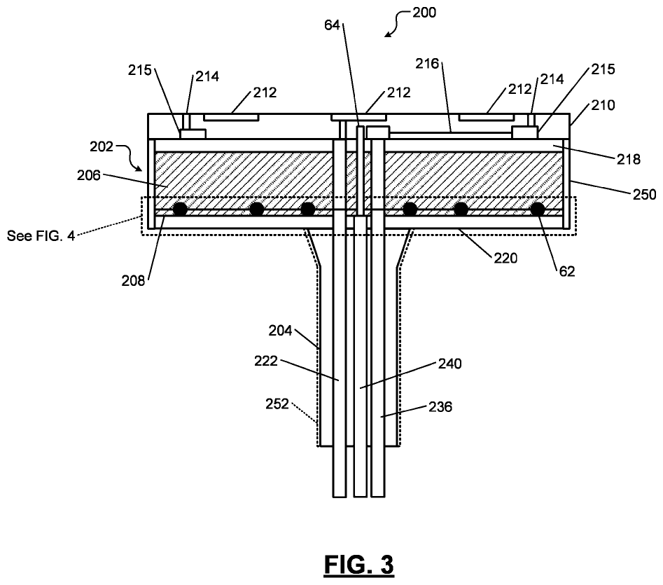

FIG. 3 shows an example of a pedestal 200 according to the present disclosure. The pedestal 200 is similar to the pedestal 14 shown in FIG. 1 and can be used in place of the pedestal 14 in the substrate processing system 10 shown in FIG. 1. However, the pedestal 200 is designed and constructed differently than the pedestal 100 shown in FIG. 2 as described below in detail. The pedestal 200 differs from the pedestal 100 shown in FIG. 2 in that the pedestal 200 is encapsulated with the second metallic material 22 as described above with reference to FIG. 1 and as described below in further detail.

Since the second metallic material 22 is resistant to the process chemistries used in the processes performed in the processing chamber 12, the second metallic material 22 prevents deterioration of the pedestal 200. Additionally, in the pedestal 200, the grooves used for vacuum clamping and supplying the edge gas are not formed in the plates of the first metallic material. Instead, as described below in detail, the grooves are formed in a top plate of the second metallic material 22 that covers a top surface of the base portion of the pedestal 200. Throughout the following description, the first and second metallic materials referenced in the construction of the pedestal 200 are the first and second metallic materials described above with reference to FIG. 1

Specifically, the pedestal 200 comprises a base portion 202 and a stem portion 204. The base portion 202 and the stem portion 204 are made of the first metallic material. In some examples, the stem portion 204 may be made entirely of the second metallic material. Alternatively, the stem portion 204 may be made of the first metallic material that is then coated or plated with the second metallic material. Examples of the first and second metallic materials are already described above and are therefore not repeated for brevity. The base portion 202 is cylindrical. The base portion 202 comprises a first plate 206 and a second plate 208. The first and second plates 206 and 208 are cylindrical. The first and second plates 206 and 208 comprise (i.e., are made of) the first metallic material. The first and second plates 206 and 208 are solid (i.e., comprise no cavities such as grooves used for vacuum clamping and supplying the edge gas). The top and bottom surfaces of the first plate 206 are flat and devoid of any features such as grooves used for vacuum clamping and supplying the edge gas. The first plate 206 is thicker than the second plate 208.

The first plate 206 forms the bulk (e.g., more than 80% or 90%) of the base portion 202 of the pedestal 200. A heater (e.g., the heater 62 shown in FIG. 1) is disposed between the first and second plates 206, 208. The second plate 208 is brazed to the first plate 206. Since the first and second plates 206 and 208 are solid, the base portion 202 does not comprise any hollow spaces (e.g., the grooves used for vacuum clamping and supplying the edge gas). The base portion 202 is a homogenous solid block of the first metallic material. Accordingly, the base portion 202 uniformly distributes heat from the heater 62 across the base portion 202.

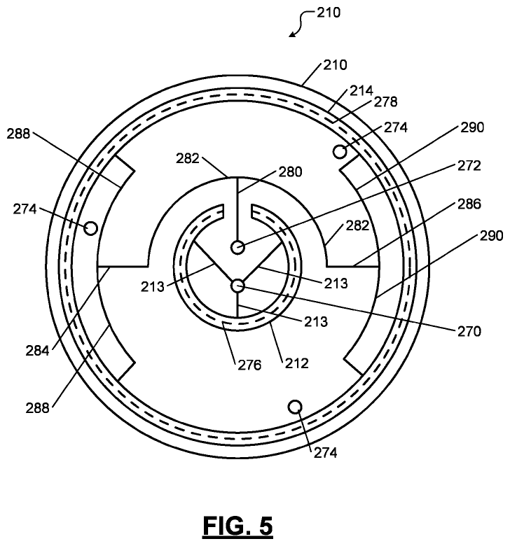

The base portion 202 is encapsulated with the second metallic material (e.g., the second metallic material 22 shown in FIG. 1) as follows. Examples of the second metallic material are already described above and are therefore not repeated for brevity. A top plate 210 comprising the second metallic material is coupled to the first plate 206 with another plate 218 disposed between the top plate 210 and the first plate 206 (explained below) using friction stir welding, brazing, diffusion bonding, or cladding technique. The top plate 210 is cylindrical. The top plate 210 is thinner than the first plate 206. The top plate 210 comprises grooves used for vacuum clamping and supplying the edge gas. The top plate 210 is shown and described below in further detail with reference to FIGS. 5-7.

Briefly, a top surface of the top plate 210 comprises grooves shown at 212 to provide vacuum clamping to clamp a substrate (e.g., the substrate 24 shown in FIG. 1) to the pedestal 200. Additionally, the top plate 210 comprises grooves 214, 215, 216 to supply the edge gas to control processing at edges of the substrate 24. The grooves 212, 214, 215, 216 are similar to the grooves 120, 130, 132, 134 of the pedestal 100 shown in FIG. 2 with the following exception. Unlike the grooves 120, 130, 132, 134, which are formed in the plate 110 of the base portion 102 of the pedestal 100, where the plate 110 is made of the first metallic material, the grooves 212, 214, 215, 216 are not formed in the first plate 206 of the pedestal 200, where the first plate 206 is made of the first metallic material. Instead, the grooves 212, 214, 215, 216 are formed in the top plate 210 made of the second metallic material. Additional details of the top plate 210 are described below with reference to FIGS. 5-7.

A bottom surface of the top plate 210 comprises plenums for providing vacuum and supplying the edge gas (shown and described in detail with reference to FIG. 5). A flat plate 218 comprising the second metallic material is interposed between the bottom surface of the top plate 210 and a top surface of the first plate 206 of the base portion 202. The flat plate 218 is cylindrical. The flat plate 218 is solid (i.e., comprises no cavities). The flat plate 218 seals the first plate 206 from the plenums in the top plate 210. The flat plate 218 is thinner than the top plate 210. The flat plate 218 can be coupled to the top surface of the first plate 206 of the base portion 202 using friction stir welding, brazing, diffusion bonding, or cladding technique. The top plate 210 can be coupled to a top surface of the flat plate 218 using diffusion bonding or another bonding method.

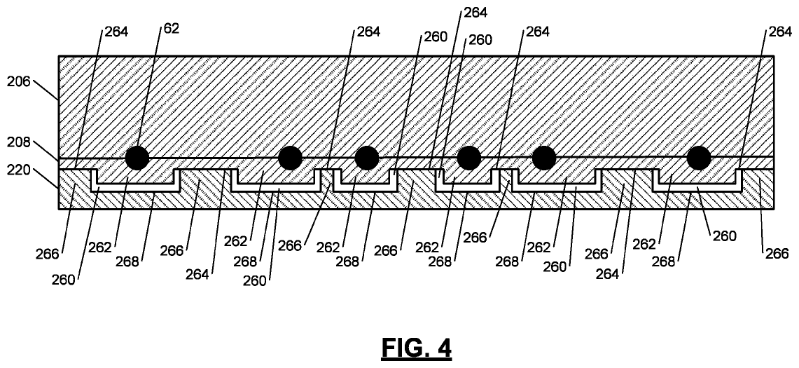

A bottom plate 220 comprising the second metallic material is bonded to a bottom surface of the second plate 208 using friction stir welding, brazing, diffusion bonding, or cladding technique. An interface between the bottom surface of the second plate 208 and a top surface of the bottom plate 220 is shown and described below in detail with reference to FIG. 4. Briefly, the bottom plate 220 is also cylindrical and is thinner than the top plate 210. The bottom plate 220 can also be thinner than the second plate 208. The bottom plate 220 may comprise gaps shown and described below in further detail with reference to FIG. 4. The gaps reduce heat transfer from the heater 62 to areas around the pedestal 200.

A conduit 222 extends through the stem portion 204 of the pedestal 200, passes through the plates 220, 208, 206, and 218, and is connected to the groove 212 near the center of the top plate 210. The conduit 222 is connected to the vacuum pump 72 (shown in FIG. 1). The vacuum pump 72 creates vacuum through the grooves 212 to clamp the substrate 24 to the top surface of the top plate 210.

The grooves 214, 215, 216 used to supply the edge gas are in fluid communication with each other but are not in fluid communication with the grooves 212. A conduit 236 extends through the stem portion 204 of the pedestal 200, passes through the plates 220, 208, 206, and 218, and is connected to the groove 216 near the center of the top plate 210. The conduit 236 supplies the edge gas through the grooves 214, 215, 216 to control processing around edges of the substrate 24.

A temperature sensor (e.g., the temperature sensor 64 shown in FIG. 1) is disposed in the first plate 206, the flat plate 218, or the top plate 210 of the base portion 202 of the pedestal 200. The temperature sensor 64 may extend to the flat plate 218 or the top plate 210 to accurately measure the temperature of the surface contacting the substrate 24. The temperature sensor 64 monitors the temperature of the pedestal 200 and the substrate 24 and is connected to the controller 80 (shown in FIG. 1). A conduit 240 extends through the stem portion 204 of the pedestal 200 and passes through the plates 220, 208, 206. Electrical connections to various components of the pedestal 200 such as the heater 62 and the temperature sensor 64 are provided through the conduit 240. The electrical connections are connected to the controller 80 (shown in FIG. 1).

The sidewalls of the first and second plates 206, 208 of the base portion 202 of the pedestal 200 are coated or plated with a layer 250 of the second metallic material. Alternatively, an annular layer 250 of the second metallic material is bonded to the sidewalls of the first and second plates 206, 208 of the base portion 202 of the pedestal 200 (e.g., using welding or another method). The layer 250 is thinner than the top plate 210 and the bottom plate 220. Thus, the top plate 210, the bottom plate 220, and the layer 250 of the second metallic material encapsulate the base portion 202 of the pedestal 200 and protect the base portion 202 of the pedestal 200 from the harsh chemistries used to process the substrate 24 and to clean the processing chamber 12 (shown in FIG. 1).

In addition, when the stem portion 204 of the pedestal comprises the first metallic material, the stem portion 204 is also coated or plated with a layer 252 of the second metallic material. The layer 252 of the second metallic material protects the stem portion 204 of the pedestal 200 from the harsh chemistries used to process the substrate 24 and to clean the processing chamber 12 (shown in FIG. 1). The layer 252 can be thinner than the layer 250. Thus, the entire pedestal 200 is encapsulated with the second metallic material that protects the pedestal 200 from the harsh chemistries used to process the substrate 24 and to clean the processing chamber 12 (shown in FIG. 1).

FIG. 4 shows the interface between the bottom surface of the second plate 208 and the top surface of the bottom plate 220 in further detail. The bottom surface of the first plate 206 and the top surface of the second plate 208 comprise grooves in which the heater 62 is disposed. The first and second plates 206, 208 are brazed together such that there is no gap between the first and second plates 206, 208. Thus, the first and second plates 206, 208 form the base portion 202 of the pedestal 200, where the base portion 202 is a homogenous solid block of the first metallic material.

The bottom surface of the second plate 208 and the top surface of the bottom plate 220 comprise annular ridges and annular grooves. The bottom surface of the second plate 208 comprises annular ridges 262 and annular grooves 264. The top surface of the bottom plate 220 comprises annular ridges 266 and annular grooves 268. When the bottom plate 220 is bonded to the second plate 208, the annular ridges 262 and the annular grooves 264 on the bottom surface of the second plate 208 fit into the annular grooves 268 and the annular ridges 266 on the top surface of the bottom plate 220, respectively.

The height of the annular ridges 262 is the same as the depth of the annular grooves 264. The height of the annular ridges 266 is the same as the depth of the annular grooves 268. The height of the annular ridges 262 is less than the depth of the annular grooves 268. The height of the annular ridges 266 is greater than the depth of the annular grooves 264. Additionally, the annular grooves 268 are wider (in the radial direction) than the annular ridges 262. The annular grooves 264 are wider (in the radial direction) than the annular ridges 266. Accordingly, when the bottom plate 220 is bonded to the second plate 208, gaps 260 are formed between the annular ridges 262 and the annular grooves 268 and between the annular ridges 266 and annular grooves 264. The gaps 260 surround the annular ridges 262 and 266.

The gaps 260 provide thermal insulation that prevents the heat from the heater 62 from transferring to areas surrounding the pedestal 200. Accordingly, maximum heat from the heater 62 is transferred to the base portion 202 of the pedestal 200, through the flat plate 218 to the top plate 210, and to the substrate 24 (shown in FIG. 3). Thus, power consumed by the heater 62 is reduced compared to that consumed in the pedestal 100 shown in FIG. 1, which is not encapsulated with the second metallic material. In other words, due to reduced heat loss, less power is supplied to the heater 62 to heat the pedestal 200 than that is supplied in the pedestal 100 to heat the substrate 24 (shown in FIG. 1).

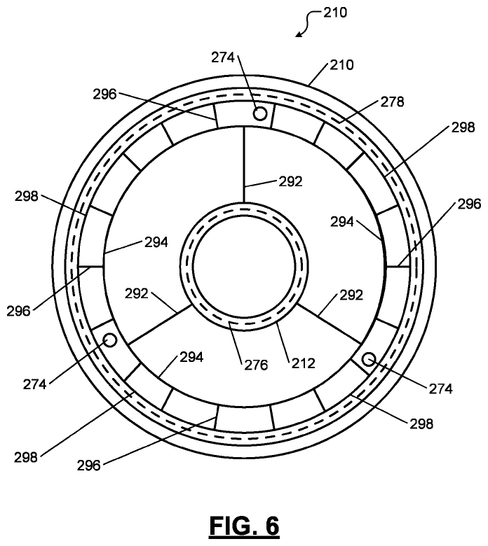

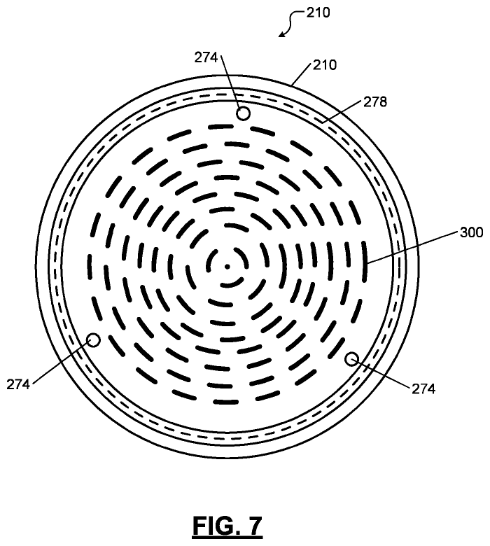

FIGS. 5 and 6 show examples of bottom and top views of the top plate 210, respectively. FIGS. 5 and 6 show an example the top plate 210 configured to provide vacuum clamping and to supply the edge gas. FIG. 7 shows another example of a top view of the top plate 210, where the top plate 210 is configured to support the substrate 24 with mesas disposed on the top surface of the top plate 210 and to also supply the edge gas.

In FIG. 5, the top plate 210 comprises two disjoint plenums that independently (i.e., separately) provide vacuum and the edge gas as explained below. Each plenum comprises various grooves. The grooves in each plenum are in fluid communication with each other. The two plenums are not in fluid communication with each other. While a configuration of grooves is described below, the configuration is only an example and can be varied.

The top plate 210 (and while not shown, all other plates of the base portion 202) comprises through holes 274 through which lift pins (not shown) are inserted to lower and raise the substrate 24. The diameter of the flat plate 218 is greater than the groove 214 used to supply the edge gas. Thus, the flat plate 218 isolates the two plenums in the top plate 210 from the base portion 202 of the pedestal 200 from the process chemistries. The flat plate 218 prevents the process chemistries from reaching the base portion 202 of the pedestal 200 through the two plenums in the top plate 210.

The bottom surface of the top plate 210 comprises holes 270 and 272. The hole 270 is connected to the conduit 222 that is connected to the vacuum pump 72 through one of the valves 70 (shown in FIG. 1). The hole 272 is connected to the conduit 236 that is connected to one of the gas sources 54 supplying the edge gas through one of the valves 70 (shown in FIG. 1).

The bottom surface of the top plate 210 comprises a plurality of grooves 213 that extend radially from the hole 270. The grooves 213 connect the hole 270 to the groove 212, which is annular. The groove 212 comprises a plurality of holes 276. The groove 212 is connected to a network of other grooves on the top surface of the top plate 210 shown in FIG. 6. The network of these grooves extends throughout the top surface of the top plate 210 to provide vacuum to clamp the substrate 24 (shown in FIG. 1) to the top surface of the top plate 210. The groove 212 and the holes 276 define a first plenum in the top plate 210 that is used to provide vacuum to clamp the substrate 24 (shown in FIG. 1) to the top surface of the top plate 210.

The bottom surface of the top plate 210 comprises a second network grooves that connect the hole 272 to the groove 214. The groove 214 comprises a plurality of holes 278 through which the edge gas is supplied around the edges of the substrate 24. The second network of grooves comprises a first groove 280 that extends radially from the hole 272 and connects to an arcuate groove 282. The arcuate groove 282 is shown for example only and can have other shapes instead. Ends of the arcuate groove 282 are connected to a pair of grooves 284, 286 that extend radially outwards. The grooves 284, 286 are connected to a pair of arcuate grooves 288, 290, respectively. Again, the grooves 288, 290 are shown as being arcuate for example only and can have other shapes instead. Ends of the arcuate grooves 288, 290 extend radially outwards and are connected to the groove 214. The grooves 280, 282, 284, 286, 288, 290, 214 are in fluid communication with the hole 272 and the conduit 236. Thus, the edge gas supplied through the hole 272 flows through the grooves 280, 282, 284, 286, 288, 290 into the groove 214. The grooves 280, 282, 284, 286, 288, 290, 214 define a second plenum in the top plate 210 that is used to supply the edge gas around the edges of the substrate 24 (shown in FIG. 1) on the top surface of the top plate 210. The grooves 280, 282, 284, 286, 288, 290, 214 are generally shown at 214, 215, 216 in FIG. 3.

In FIG. 6, the top surface of the top plate 210 comprises the holes 278 through which the edge gas is supplied as described above. The top surface of the top plate 210 comprises the groove 212 and the holes 276. The groove 212 is connected to a network of annular and radial grooves that extends throughout the top surface of the top plate 210 to provide vacuum to clamp the substrate 24 (shown in FIG. 1) to the top surface of the top plate 210. A plurality of grooves 292 extend radially outwards from the groove 212. The grooves 292 are connected to a first annular groove 294. A plurality of grooves 296 extend radially outwards from the first annular groove 294. The grooves 296 are connected to a second annular groove 298.

The diameter of the first annular groove 294 is greater than the diameter of the groove 212. The diameter of the second annular groove 298 is greater than the diameter of the first annular groove 294. The diameter of the second annular groove 298 is less than the diameter of the groove 214. In some examples, the diameter of the groove 214 can be slightly less or slightly greater than the diameter of the substrate 24. In other examples, the diameter of the groove 214 can be the same as the diameter of the substrate 24.

While only two annular grooves 294, 298 are shown for example only, the top surface of the top plate 210 can comprise additional annular grooves similar to the annular grooves 294, 298 and additional interconnecting radial grooves similar to the grooves 292, 296 that connect the additional annular grooves to each other and to the network of the grooves 212, 292, 294, 296, 298. The grooves 212, 292, 294, 296, 298 are generally shown at 212 in FIG. 3. The grooves 212, 292, 294, 296, 298 are in fluid communication with the hole 270 and the conduit 222. The grooves 212, 292, 294, 296, 298 provide vacuum to clamp the substrate 24 (shown in FIG. 1) to the top surface of the top plate 210.

The groove 214 circumscribes the grooves 212, 292, 294, 296, 298 used to provide vacuum clamping. The grooves 212, 213, 292, 294, 296, 298, the hole 270, the holes 276, and the conduit 222 are disjoint from and are not in fluid communication with the grooves 280, 282, 284, 286, 288, 290, 214, the hole 272, the holes 278, and the conduit 236.

Depending on the support mechanism used to support the substrate 24 on the pedestal 200 and whether the edge gas is supplied, the pedestal 200 can comprise fewer or different features than those shown in FIGS. 3-6. For example, if the pedestal 200 is designed to not supply the edge gas and to provide vacuum clamping, the conduit 236 can be omitted. Further, elements 214, 278, 280, 282, 284, 286, 288, 290, 214, 272 can be omitted from the top plate 210. Thus, if the pedestal 200 is designed to not supply the edge gas and to provide vacuum clamping, the top plate 210 can comprise only the grooves 212, 213, 292, 294, 296, 298, the hole 270, the holes 276, and the conduit 222 for providing vacuum clamping as shown and described above with reference to FIGS. 5 and 6. All other elements and features of the pedestal 200 remain unchanged as described above with reference to FIGS. 3-6.

Alternatively, if the pedestal 200 is designed to not provide vacuum clamping and to supply the edge gas, the conduit 222 can be omitted. Further, elements 212, 213, 292, 294, 296, 298, 270, 276 can be omitted from the top plate 210. As shown in a top view of the top plate 210 in FIG. 7, mesas 300 can be provided on the top surface of the top plate 210. The mesas 300 can extend from the center of the top plate 210 up to an inner diameter of the groove 214. Thus, if the pedestal 200 is designed to not provide vacuum clamping and to supply the edge gas, the top plate 210 can comprise only the mesas 300, the grooves 280, 282, 284, 286, 288, 290, 214, the hole 272, and the holes 278 as shown and described above with reference to FIGS. 5 and 6. All other elements and features of the pedestal 200 remain unchanged as described above with reference to FIGS. 3-6.

In another design, if the pedestal 200 is designed to not provide vacuum clamping and to not supply the edge gas, the conduits 222 and 236 can be omitted. Further, elements 212, 213, 292, 294, 296, 298, 270, 276 and elements 280, 282, 284, 286, 288, 290, 214, 272, 278 can be omitted from the top plate 210. Only the mesas 300 shown in FIG. 7 can be provided on the top surface of the top plate 210. The mesas 300 can extend from the center of the top plate 210 up to an outer diameter of the top plate 210. Thus, if the pedestal 200 is designed to not provide vacuum clamping and to not supply the edge gas, the top plate 210 can comprise only the mesas 300 on the top surface of the top plate 210. The bottom surface of the top plate 210 can be flat and devoid of any features such as the grooves and holes shown in FIGS. 5 and 6. In this design, the flat plate 218 can also be omitted. Thus, in this design, the bottom surface of the top plate 210 can be bonded directly to the top surface of the first plate 206 of the base portion 202 of the pedestal 200. All other elements and features of the pedestal 200 remain unchanged as described above with reference to FIGS. 3-6.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the examples is described above as having certain features, any one or more of those features described with respect to any one of the examples of the disclosure can be implemented in and/or combined with features of any of the other examples, even if that combination is not explicitly described. In other words, the described examples are not mutually exclusive, and permutations of one or more examples with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate.

The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

Program instructions may be instructions communicated to the controller in the form of various individual settings (or program files), defining operational parameters for carrying out a particular process on or for a semiconductor wafer or to a system. The operational parameters may, in some examples, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A pedestal for a substrate processing system, the pedestal comprising:
a base portion comprising a first metallic material;
a stem portion coupled to the base portion; and
a second metallic material encapsulating the base portion, the second metallic material being different than the first metallic material.

2. The pedestal of claim 1 wherein the first metallic material is selected from a group consisting of aluminum, stainless steel, and an alloy of aluminum and wherein the second metallic material is nickel or nickel alloy.

3. The pedestal of claim 1 wherein the second metallic material has a greater resistance than the first metallic material to process chemistries used to process a substrate on the pedestal in a processing chamber of the substrate processing system and to clean the processing chamber.

4. The pedestal of claim 1 wherein the first and second metallic materials are thermally compatible with each other.

5. The pedestal of claim 1 wherein a first thickness of the second metallic material on a top surface of the base portion is greater than a second thickness of the second metallic material on a bottom surface and a side surface of the base portion.

6. The pedestal of claim 1 wherein the stem portion is encapsulated with the second metallic material and wherein at least two different surface areas of the base portion and the stem portion are encapsulated with the second metallic material using different encapsulating methods.

7. The pedestal of claim 1 wherein the stem portion comprises the second metallic material.

8. The pedestal of claim 1 wherein the stem portion comprises the first metallic material and wherein an outer surface of the stem portion is encapsulated with the second metallic material.

9. The pedestal of claim 1 wherein the base portion comprises:
a first plate comprising the first metallic material, the first plate comprising a first surface and a second surface;
a second plate comprising the first metallic material, the second plate comprising a first surface and a second surface, the first surface of the second plate bonded to the second surface of the first plate, sidewalls of the first and second plates covered with a first layer of the second metallic material;
a third plate comprising the second metallic material, the third plate comprising a first surface and a second surface;
a fourth plate comprising the second metallic material, the fourth plate comprising a first surface and a second surface, the first surface of the fourth plate is bonded to the second surface of the third plate, the second surface of the fourth plate is bonded to the first surface of the first plate; and
a fifth plate comprising the second metallic material, the fifth plate comprising a first surface and a second surface, the first surface of the fifth plate is bonded to the second surface of the second plate, the second surface of the fifth plate is bonded to the stem portion.

10. The pedestal of claim 9 wherein the third plate has a thickness greater than a thickness of the fifth plate and less than a thickness of the first plate, wherein the first plate has a thickness greater than the second plate, and wherein the fifth plate has a thickness less than the second plate.

11. The pedestal of claim 10 wherein the stem portion comprises the first metallic material and is covered with a second layer of the second metallic material, and wherein the second layer is thinner than the third and fifth plates and the first layer of the second metallic material covering the sidewalls of the first and second plates.

12. The pedestal of claim 9 wherein the third plate comprises a set of grooves, the pedestal further comprising a conduit coupled to the set of grooves and extending through the stem portion, the fifth plate, the second plate, the first plate, and the fourth plate, and wherein the fourth plate seals the first plate from the set of grooves.

13. A system comprising the pedestal of claim 12 and further comprising a vacuum pump coupled to the conduit, the vacuum pump configured to create vacuum in the set of grooves to clamp a substrate to the first surface of the third plate.

14. A system comprising the pedestal of claim 12 wherein the third plate comprises a set of holes around a periphery of the first surface of the third plate, the set of holes in fluid communication with the set of grooves, and wherein the system further comprises a gas source coupled to the conduit, the gas source configured to supply a gas through the set of grooves and the set of holes.

15. The pedestal of claim 9 wherein the third plate comprises a first set of grooves, a second set of grooves, and a set of holes around a periphery of the first surface of the third plate, the set of holes in fluid communication with the second set of grooves and the first set of grooves disjoint from the second set of grooves and the set of holes.

16. The pedestal of claim 15 further comprising a first conduit and a second conduit disposed through the stem portion and at least partially through the base portion, wherein the first conduit is coupled to the first set of grooves, the second conduit is coupled to the second set of grooves, and the fourth plate seals the first plate from the first and second sets of grooves and the set of holes.

17. A system comprising the pedestal of claim 16 and further comprising:
a vacuum pump coupled to the first conduit, the vacuum pump configured to create vacuum in the first set of grooves to clamp a substrate to the first surface of the third plate; and
a gas source coupled to the second conduit, the gas source configured to supply a gas through the second set of grooves and the set of holes.

18. The pedestal of claim 9 further comprising a heater disposed between the first and second plates and wherein an interface between the second plate and the fifth plate comprise gaps configured to reduce heat transfer from the fifth plate to areas around the pedestal.

19. The pedestal of claim 9 further comprising a heater disposed between the first and second plates, wherein:
the second surface of the second plate and the first surface of the fifth plate comprise ridges and grooves, the heater being aligned with the ridges on the second surface of the second plate;
the ridges on the first surface of the fifth plate are bonded to the grooves on the second surface of the second plate;
the grooves on the first surface of the fifth plate are configured to provide gaps around the ridges on the second surface of the second plate; and
the gaps are configured to reduce heat transfer from the fifth plate to areas around the pedestal.

20. The pedestal of claim 1 wherein the base portion comprises:
a first plate comprising the first metallic material, the first plate comprising a first surface and a second surface;
a second plate comprising the first metallic material, the second plate comprising a first surface and a second surface, the first surface of the second plate bonded to the second surface of the first plate, sidewalls of the first and second plates covered with a first layer of the second metallic material;
a third plate comprising the second metallic material, the third plate comprising a first surface and a second surface, the first surface of the third plate comprising protrusions to support a substrate, the second surface of the third plate bonded to the first surface of the first plate; and
a fourth plate comprising the second metallic material, the fourth plate comprising a first surface and a second surface, the first surface of the fourth plate is bonded to the second surface of the second plate, the second surface of the fourth plate is bonded to the stem portion.

21. The pedestal of claim 20 wherein the third plate has a thickness greater than the fourth plate and thinner than the first plate, wherein the first plate has a thickness greater than the second plate, and wherein the fourth plate has a thickness less than the second plate.

22. The pedestal of claim 20 wherein the stem portion comprises the first metallic material and is covered with a second layer of the second metallic material, and wherein the second layer is thinner than the third and fourth plates and the first layer.

23. The pedestal of claim 20 wherein the third plate comprises a set of grooves, the pedestal further comprising a conduit coupled to the set of grooves through the stem portion, the fourth plate, the second plate, and the first plate, the pedestal further comprising a fifth plate that seals the first plate from the set of grooves.

24. A system comprising the pedestal of claim 23 wherein the third plate comprises a set of holes around a periphery of the first surface of the third plate, the set of holes in fluid communication with the set of grooves, wherein the fifth plate seals the first plate from the set of holes, and wherein the system further comprises a gas source coupled to the conduit, the gas source configured to supply a gas through the set of grooves and the set of holes.

25. The pedestal of claim 20 further comprising a heater disposed between the first and second plates and wherein an interface between the second plate and the fourth plate comprise gaps configured to reduce heat transfer from the fourth plate to areas around the pedestal.

26. The pedestal of claim 20 further comprising a heater disposed between the first and second plates, wherein:
the second surface of the second plate and the first surface of the fourth plate comprise ridges and grooves, the heater being aligned with the ridges on the second surface of the second plate;
the ridges on the first surface of the fourth plate are bonded to the grooves on the second surface of the second plate;
the grooves on the first surface of the fourth plate are configured to provide gaps around the ridges on the second surface of the second plate; and
the gaps are configured to reduce heat transfer from the fourth plate to areas around the pedestal.
